(19) United States
(12) Patent Application Publication
(10) Pub. No.: US 2017/0062252 A1
(43) Pub. Date: Mar. 2, 2017

(54) LASER MARKING DEVICE AND METHOD THEREOF

(71) Applicant: E&R Engineering Corp., Kaohsiung (TW)

(72) Inventors: Wen Ren WU, Kaohsiung (TW); Cho Chun CHUNG, Kaohsiung (TW)

(73) Assignee: E&R Engineering Corp., Kaohsiung (TW)

(21) Appl. No.: 15/051,841

(22) Filed: Feb. 24, 2016

(30) Foreign Application Priority Data
Sep. 2, 2015 (TW) 104128977

(51) Int. Cl. H01L 21/67; H01L 21/268; B23K 26/08; B23K 26/362; B23K 26/402; H01L 23/544; H01L 21/66

(52) U.S. Cl. CPC H01L 21/67282; H01L 23/544; H01L 21/268; H01L 22/20; B23K 26/362; B23K 26/402; B23K 26/0823

(57) ABSTRACT

The present disclosure relates to a laser marking device and a method thereof. The laser marking device comprises a laser system, a wafer leveling system, a first imaging system and a mobile system: the wafer leveling system carries and levels a warped wafer to be processed; the mobile system underneath properly adjusts a position of the wafer; the first imaging system detects the wafer to recognize a product category and positioning status; the laser system underneath labels laser marks on the wafer; all wafers are marked in the cyclic process.

### BACKGROUND OF THE INVENTION

1) Field of the Invention

The present disclosure relates to a laser marking device and a method thereof for wafers, particularly a laser marking device and a method thereof to level large-size warped wafers prior to marking for no laser marks shifted.

2) Description of the Prior Art

In recent years, smart phones have been a part of every consumer's life in addition to all types of wearable devices getting more popular with the general public. It can be seen from the trend of consumer goods that merchandise is being miniaturized for strengthened computing power.

Basically, the consumer goods are electronic devices characteristic of compact sizes and good computing power, both of which can be promoted with manufacturing processes based on the well-known “Moore's Law”. In semiconductor manufacturing processes, the laser marking process depends on the laser beam to label marks on wafers for the following die-saw process.

There haven been multiple patents for marking on wafers presented as follows:

Publication No. TW I233197 discloses a chip scale marker characterized in that: a laser system is used in laser marking; a wafer support on which a wafer to be marked is carried comprises a vacuum panel centrally mounted on the wafer support to absorb the wafer and a wafer spin unit installed around the vacuum panel and being opposite to an open region of the laser system; a camera over the wafer support takes photos of the wafer; a warp removal unit over the wafer support eliminates any warp of the wafer.

Publication No. TW I310582 discloses a method for laser marking on wafers, characterized in that a wafer is carried on a transparent carrier plate with the wafer's back horizontally contacting the transparent carrier plate. For laser marks labeled on a wafer, a laser beam through the transparent carrier plate is projected on the back of a wafer for generation of at least a laser mark without the problem that no laser mark is labeled on a thinned wafer conventionally.

Publication No. TW I351070 discloses a method of marking a wafer characterized in that: at least two reference marks on a wafer with a plurality of dies at one side are checked in a wafer alignment step and the wafer is marked with a laser beam. Moreover, a method of marking a wafer is available to marking defective dies on a wafer but characteristic of more advantages such as less contamination compared with conventional ink marks labeled on defective dies, fewer working hours and workshop space, and permanent marks better than ink marks labeled by existing wafer testers or ink-based machines.

Publication No. TW I288431 discloses a method of labeling identification marks on wafers and a device thereof. As shown in Publication No. TW I288431, a laser beam is projected on a default position of an aligned wafer and labels an identification mark on the wafer. With the laser beam projected, a gas flow is directed to the default position on the wafer for removal of any particle created by the laser beam on the wafer surface. The device for labeling identification marks on wafers is provided with a venting portion for exhaust of dust gases. As such, there is neither particle attached on the surface of a wafer nor faults of the device induced by particles in subsequent steps.

However, the yield rate of a wafer which is spin and leveled and pressed by a leveling device repeatedly is affected; moreover, a wafer with marks labeled but status not recorded is neither monitored immediately nor traced afterward.

To settle the above issues, the present disclosure is to offer a laser marking device and a method thereof for marks on wafers.

### SUMMARY OF THE INVENTION

In virtue of above issues, the present disclosure offers a laser marking device and a method thereof, characterized in that a wafer is carried by a wafer leveling system and spin and shifted by a mobile system but not completely pressed.

The present disclosure is to provide a laser marking device and a method thereof, characterized in that a wafer is neither pressed extensively (repeatedly and entirely) nor structurally affected by stress.

The present disclosure is to provide a laser marking device and a method thereof, characterized in that the status of a wafer which underwent a manufacturing process is recorded by a second imaging system.

The present disclosure is to provide a laser marking device and a method thereof, characterized in that a mobile system contributes to spins and translations for flexible processing.

The present disclosure is to provide a laser marking device and a method thereof, characterized in that a rotary mechanism comprises a gearwheel ring component consisting of an upper ring, a lower ring and a plurality of springs for minimal errors during spins.

To this end, a laser marking device is embodied with technical measures as follows. A laser marking device in the present disclosure comprises a laser system, a mobile system over the laser system, a wafer leveling system over the mobile system and a first imaging system over the wafer leveling system and is characterized in that the wafer leveling system carries and levels a warped wafer to be processed, the mobile system underneath properly adjusts a position of the wafer, the first imaging system detects the wafer to recognize a product category shown on the wafer and positioning status, and the laser system underneath labels laser marks on the wafer.

Moreover, a laser marking device further depends on following technical measures to realize purposes and techniques.

In the laser marking device, the wafer leveling system comprises a carrier module, a fixture module, a dynamic module and a vacuum module.

In the laser marking device, the wafer leveling system is opposite to a second imaging system underneath.

In the laser marking device, the mobile system comprises a rotary mechanism and a translational mechanism.

In the laser marking device, the rotary mechanism comprises a gearwheel ring component, a pinion component and a dynamic component.

In the laser marking device, the gearwheel ring component comprises an upper ring, a lower ring and a plurality of springs.

A method for laser marking comprises steps as follows: (a) a wafer leveling system carries and levels a wafer; (b) a first imaging system detects the topography on the upper surface of the wafer to measure positions of a plurality of dies and recognize a plurality of locations for laser marking based on the dies; (c) a laser system refers to information for laser marking on the wafer and marks the wafer at the lower surface through an unfilled corner; (d) the wafer leveling system is spin by a mobile system; (e) the wafer leveling system is horizontally shifted by a mobile system; steps (b) to (e) may be conducted repeatedly.

Moreover, a method for laser marking further depends on following technical measures to realize purposes and techniques.

In the method for laser marking, the wafer is lifted by dynamic modules in the wafer leveling system after step (c).

In the method for laser marking, the wafer is lowered by the dynamic modules in the wafer leveling system after step (d).

In the method for laser marking, a second imaging system detects the topography on the back of the wafer and records a plurality of laser marks thereon after step (c).

In contrast to conventional techniques, a laser marking device and a method thereof are characteristic of effects as follows: (1) reduced surface stress on a wafer; (2) less damage to a wafer during processing; (3) reviews and recognitions of laser marks on a wafer recorded by a second imaging system.

### BRIEF DESCRIPTIONS OF THE DRAWINGS

FIG. 1 is an exploded view of a laser marking device in a preferred embodiment;

FIG. 2 is a first schematic view of a laser marking device in a preferred embodiment;

FIG. 3 is a schematic view of a wafer leveling system of a laser marking device in a preferred embodiment;

FIG. 4 is a schematic view which illustrates a wafer leveling system of a laser marking device is lifted in a preferred embodiment;

FIG. 5 is an exploded view of a wafer leveling system of a laser marking device in a preferred embodiment;

FIG. 6 is an exploded view of a rotary mechanism of a laser marking device in a preferred embodiment;

FIG. 7a is a first schematic view of a rotary mechanism of a laser marking device in a preferred embodiment;

FIG. 7b is a second schematic view of a rotary mechanism of a laser marking device in a preferred embodiment;

FIG. 7c is a third schematic view of a rotary mechanism of a laser marking device in a preferred embodiment;

FIG. 7d is a fourth schematic view of a rotary mechanism of a laser marking device in a preferred embodiment;

FIG. 8 is a second schematic view of a laser marking device in a preferred embodiment;

FIG. 9 is a third schematic view of a laser marking device in a preferred embodiment;

FIG. 10 is a fourth schematic view of a laser marking device in a preferred embodiment;

FIG. 11 is a first flowchart of a laser marking device in a preferred embodiment; and

FIG. 12 is a second flowchart of a laser marking device in a preferred embodiment.

### DETAILED DESCRIPTIONS OF THE PREFERRED EMBODIMENTS

A laser marking device and a method thereof will be further explained in preferred embodiments for clear understanding of purposes, characteristics and effects.

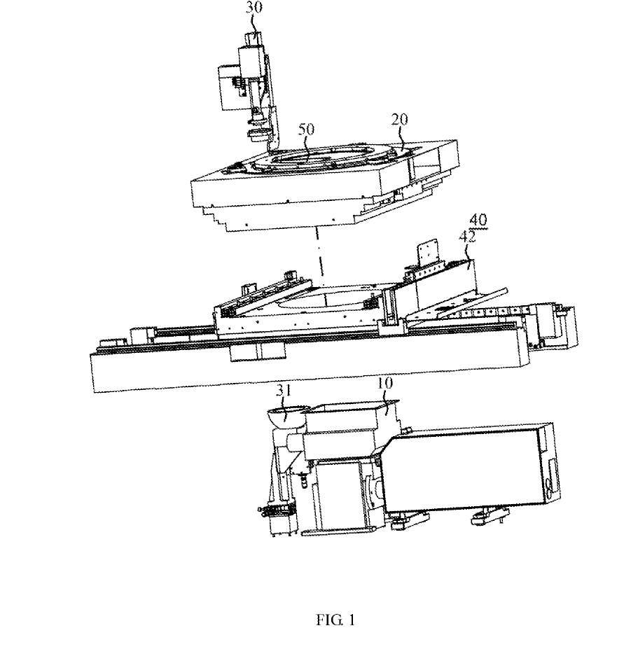

FIG. 1 to FIG. 12 present a laser marking device and a method thereof in preferred embodiments. Referring to FIG. 1 which illustrates a laser marking device comprises a laser system (10), a wafer leveling system (20), a first imaging system (30) and a mobile system (40).

Specifically, the laser system (10) is a LASER (Light Amplification by Stimulated Emission of Radiation) generation device to amplify stimulated radiation, which is generated according to three elements such as “source stimulation”, “medium gain” and “resonant structure”, for extensive applications in precision machining and semiconductor industries because of some characteristics like no machining stress and precision and is further supplemented by a dust-arrester installation around for collection of powdered by-products.

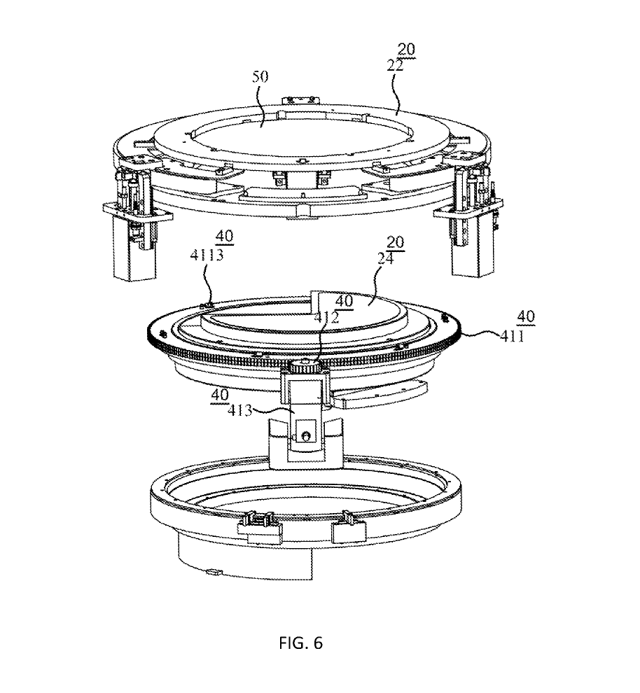

Referring to FIGS. 5 and 6 which illustrate the wafer leveling system (20) comprises a carrier module (21), a fixture module (22), dynamic modules (23) and a vacuum module (24): the carrier module (21) is divided into a six-claw structure on which a wafer (50) is carried and a stationary base underneath the wafer wherein the six-claw structure is driven by kinetic energy from the dynamic modules (23) for up/down movements and the stationary base of the carrier module (21) under the wafer (50) contacts the rim of the lower surface of the wafer (50); the fixture module (22) is a leveling device which contacts the rim of the upper surface of the wafer (50) and keeps a stable position relative to the carrier module (21) through magnetic force; the dynamic modules (23) provide displacement power from electricity-driven motors; the vacuum module (24) is covered with antistatic material at its upper surface adjacent to the wafer (50), links a vacuum pump underneath to absorb the lower surface of the wafer (50) through evenly-distributed pores and level the wafer (50), and develops an unfilled corner at which the wafer (50) is not absorbed for convenient operations.

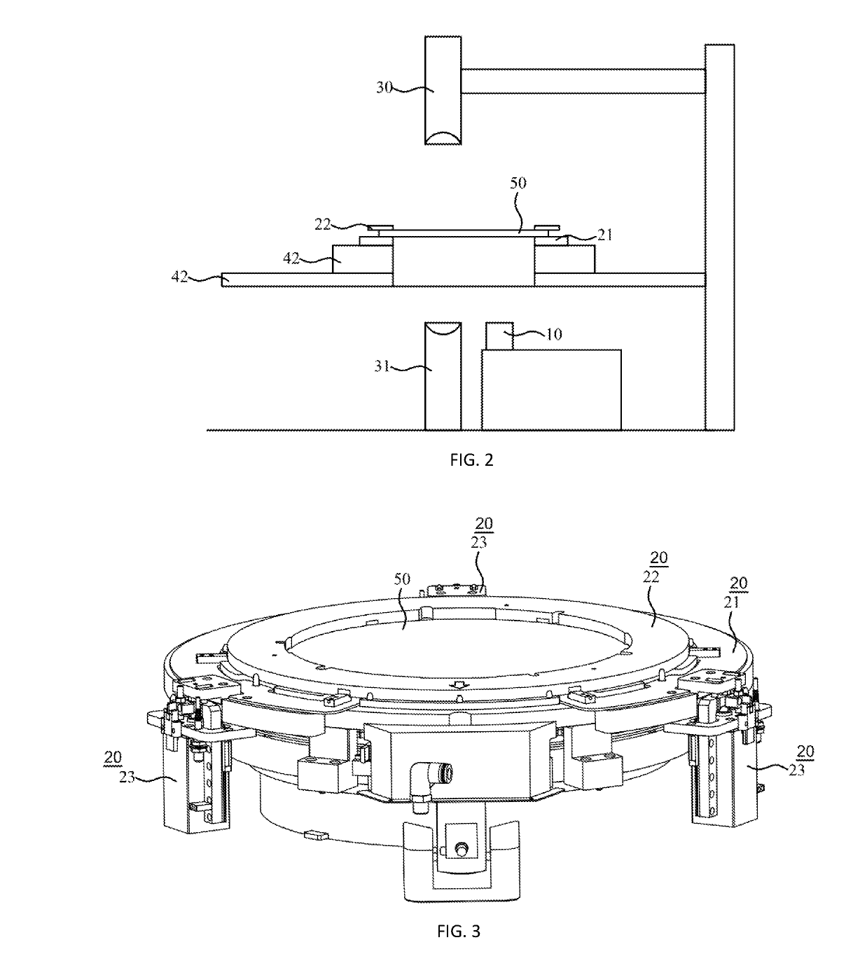

Referring to FIGS. 1 and 2 which illustrate the first imaging system (30) is an video installation mounted over the wafer (50) to detect the upper surface of the wafer (50) and electrically connected to a backend terminal device for exchanges of detected images by which a layout (product category/positioning status) of chips on the wafer (50) is recognized and the laser system (10) marks the wafer (50) at the lower surface.

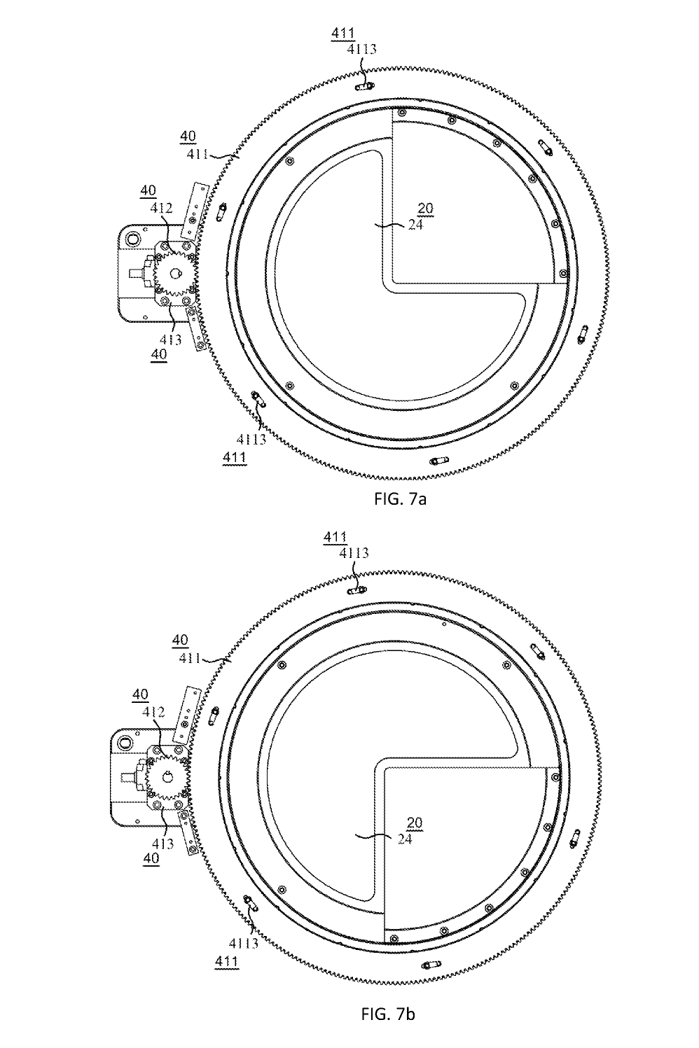

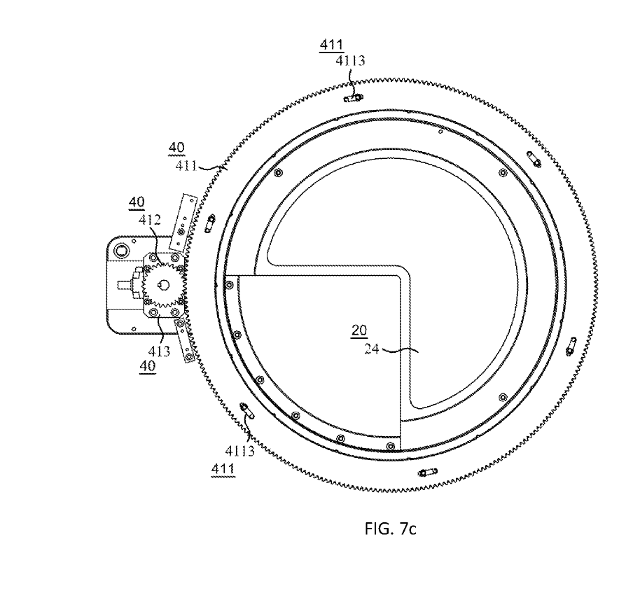

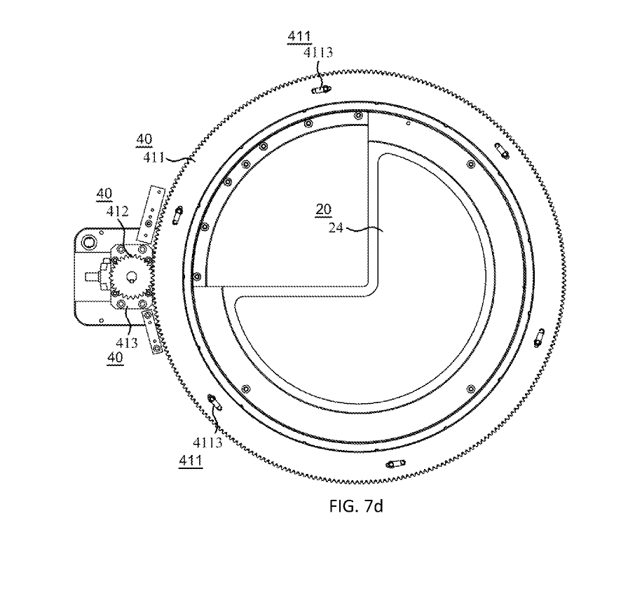

Referring to FIGS. 1, 2, 6 and 7a which illustrate the mobile system (40) comprises a rotary mechanism (41) and a translational mechanism (42): the rotary mechanism (41) supports the wafer leveling system (20) to spin the wafer (50) and comprises a gearwheel ring component (411), a pinion component (412) and a dynamic component (413) (as shown in FIG. 7a) wherein the dynamic component (413) provides power to drive the pinion component (412), the gearwheel ring component (411) linking the pinion component (412), and the vacuum module (24) securely connected to the gearwheel ring component (411); the translational mechanism (42) is an XY sliding table which drives the wafer leveling system (20) to shift along X and Y axes, as shown in FIG. 10.

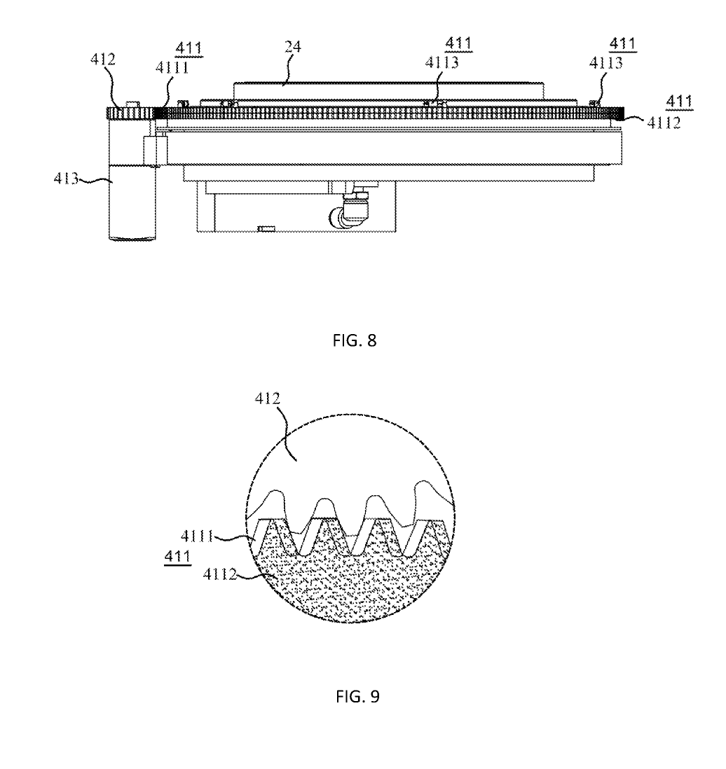

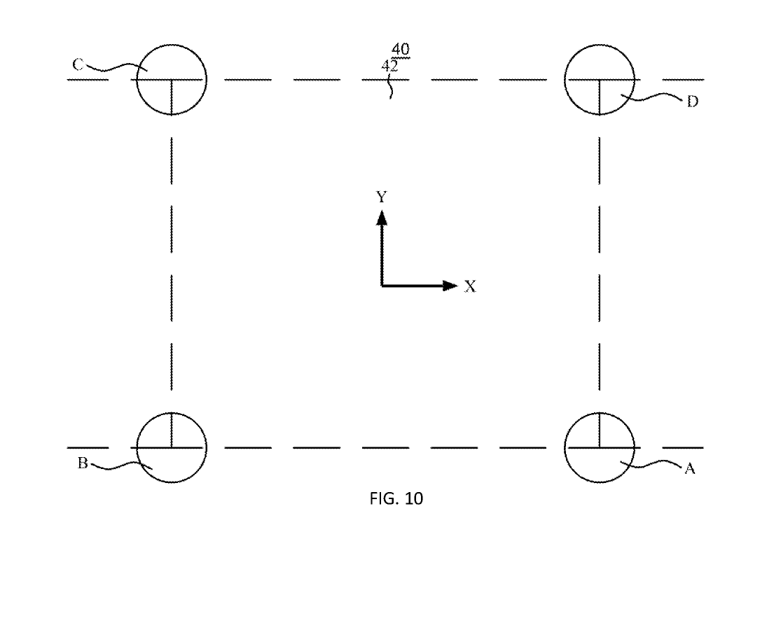

Preferably, as shown in FIGS. 1 and 2, the wafer leveling system (20) is opposite to a second imaging system (31) underneath which records laser marks labeled on the wafer (50) completely for tracing or improving a manufacturing process when the wafer (50) stays in the wafer leveling system (20); moreover, as shown in FIGS. 7a and 8, the gearwheel ring component (411) comprises an upper ring (4111), a lower ring (4112) and a plurality of springs (4113) wherein the upper ring (4111) is stacked on the lower ring (4112) and the springs (4113) stay above the upper ring (4111) and function as fasteners fixing the upper ring (4111) and the lower ring (4112); as shown in FIG. 9, the vacuum module (24) is rotated steadily because the upper ring (4111) and the lower ring (4112) fix and are slightly staggered from each other through the springs (4113) and the pinion component (412) tightly contacts the gearwheel ring component (411).

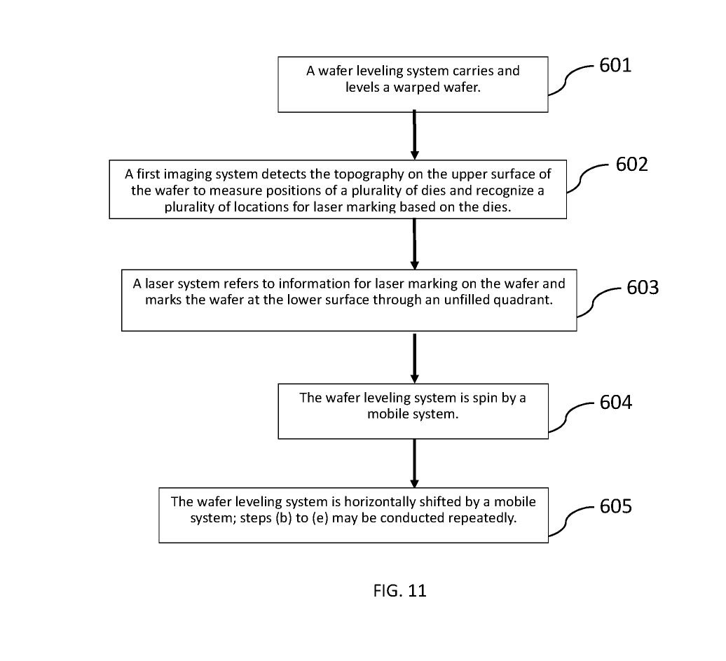

Referring to FIG. 11 which illustrates a method for laser marking: step (a): a wafer leveling system carries and levels a wafer (601); step (b): a first imaging system detects the topography on the upper surface of the wafer to measure positions of a plurality of dies and recognize a plurality of locations for laser marking based on the dies (602); step (c): a laser system refers to information for laser marking on the wafer and marks the wafer at the lower surface through an unfilled corner (603); step (d): the wafer leveling system is spin by a mobile system (604); step (e): the wafer leveling system is horizontally shifted by a mobile system (605). The steps (b) to (e) may be conducted repeatedly.

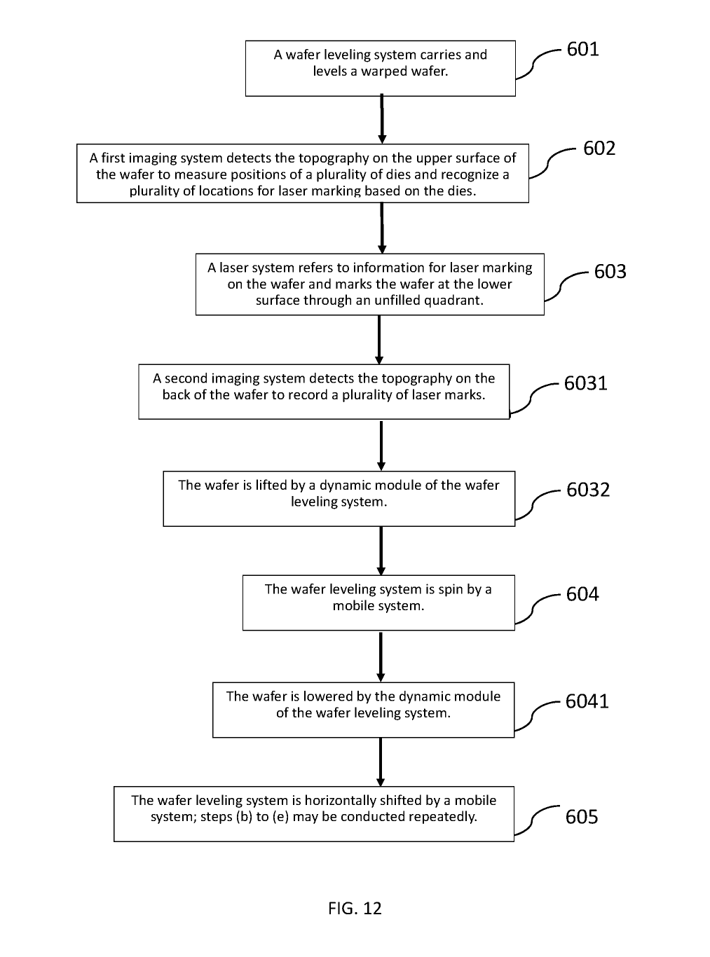

Preferably, referring to FIG. 12 which illustrates other steps: step (c2) after step (c): the wafer is lifted by a dynamic module of the wafer leveling system (6032); step (dl) after step (d): the wafer is lowered by the dynamic module of the wafer leveling system (6041); step (c1) after step (c): a second imaging system detects the topography on the back of the wafer to record a plurality of laser marks (6031).

A laser marking device and a method thereof in the present disclosure are described in preferred embodiments in which a process to use the laser marking device is presented in detail.

Referring to FIGS. 2 and 3 and FIG. 12 (step (a) (601)) which illustrate the wafer (50) is leveled according to conditions as follows: the rims of upper and lower surfaces of the wafer (50) are contacted by the fixture module (22) and the carrier module (21), respectively; the lower surface of the wafer (50) (as shown in FIG. 6) is partially absorbed by the vacuum module (24) on the basis of air pressure. Moreover, both the wafer leveling system (20) and the wafer (50) on the translational mechanism (42) stay at position A, as shown in FIG. 10.

Referring to FIGS. 1 and 2 that illustrate the first imaging system (30) detects the topography on the upper surface of the wafer (50) to measure and recognize positions of a plurality of dies for labeling a plurality of laser marks in the next step.

Referring to FIGS. 2 and 7a which illustrate the laser system (10), which refers to information for laser marks to be printed, labels laser marks at the lower surface of the wafer (50) through the unfilled corner of the vacuum module (24) (FIG. 7a).

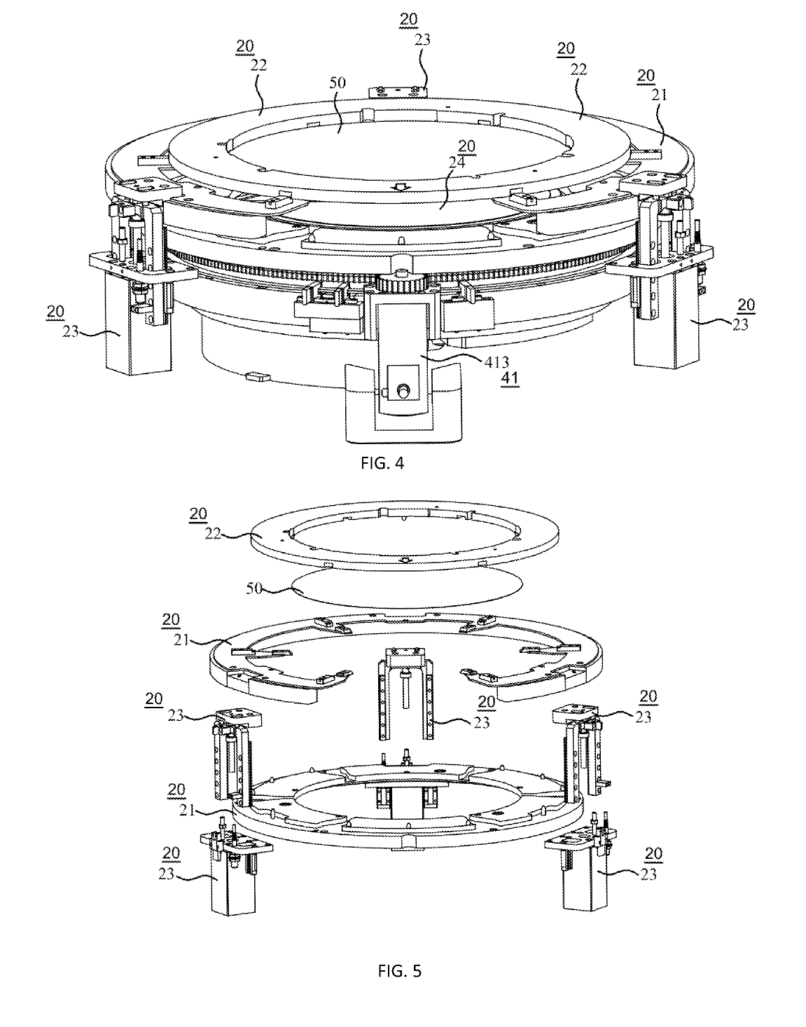

Referring to FIG. 3 to FIG. 4 that illustrate the six-claw structure of the carrier module (21) on which the wafer (50) is carried is lifted by the surrounding dynamic modules (23) (FIG. 4) and the wafer (50) is not riskily contacted or rubbed by the vacuum module (24); moreover, the pinion component (412) is driven by the dynamic component (413) for a counterclockwise spin and followed by the gearwheel ring component (411) for a clockwise spin so that the vacuum module (24) is actuated finally, as shown from FIG. 7a to FIG. 7b.

Referring to FIG. 4 to FIG. 3 that illustrate the six-claw structure of the carrier module (21) on which the wafer (50) is carried is lowered by the surrounding dynamic modules (23) (FIG. 3) and the vacuum module (24) approaches and contacts the wafer (50); moreover, both the wafer leveling system (20) and the wafer (50) are shifted to position B by the translational mechanism (42) along the negative X-axis, as shown in FIG. 10.

Referring to FIGS. 1 and 2 which illustrate the first imaging system (30) detects the topography on the upper surface of the wafer (50) to measure and recognize shifted positions of a plurality of dies for labeling a plurality of laser marks in the next step.

Referring to FIGS. 2 and 7b which illustrate the laser system (10), which refers to information for laser marks to be printed, labels laser marks at the lower surface of the wafer (50) through the unfilled corner of the vacuum module (24) (FIG. 7b).

Referring to FIG. 3 to FIG. 4 that illustrate the six-claw structure of the carrier module (21) on which the wafer (50) is carried is lifted by the surrounding dynamic modules (23) (FIG. 4) and the wafer (50) is not riskily contacted or rubbed by the vacuum module (24); moreover, the pinion component (412) is driven by the dynamic component (413) for a counterclockwise spin and followed by the gearwheel ring component (411) for a clockwise spin so that the vacuum module (24) is actuated finally, as shown from FIG. 7b to FIG. 7c.

Referring to FIG. 4 to FIG. 3 that illustrate the six-claw structure of the carrier module (21) on which the wafer (50) is carried is lowered by the surrounding dynamic modules (23) (FIG. 3) and the vacuum module (24) approaches and contacts the wafer (50); moreover, both the wafer leveling system (20) and the wafer (50) are shifted to position C by the translational mechanism (42) along the positive Y-axis, as shown in FIG. 10.

Referring to FIGS. 1 and 2 which illustrate the first imaging system (30) detects the topography on the upper surface of the wafer (50) to measure and recognize shifted positions of a plurality of dies for labeling a plurality of laser marks in the next step.

Referring to FIGS. 2 and 7c which illustrate the laser system (10), which refers to information for laser marks to be printed, labels laser marks at the lower surface of the wafer (50) through the unfilled corner of the vacuum module (24) (FIG. 7c).

Referring to FIG. 3 to FIG. 4 that illustrate the six-claw structure of the carrier module (21) on which the wafer (50) is carried is lifted by the surrounding dynamic modules (23) (FIG. 4) and the wafer (50) is not riskily contacted or rubbed by the vacuum module (24); moreover, the pinion component (412) is driven by the dynamic component (413) for a counterclockwise spin and followed by the gearwheel ring component (411) for a clockwise spin so that the vacuum module (24) is actuated finally, as shown from FIG. 7c to FIG. 7d.

Referring to FIG. 4 to FIG. 3 that illustrate the six-claw structure of the carrier module (21) on which the wafer (50) is carried is lowered by the surrounding dynamic modules (23) (FIG. 3) and the vacuum module (24) approaches and contacts the wafer (50); moreover, both the wafer leveling system (20) and the wafer (50) are shifted to position D by the translational mechanism (42) along the positive X-axis, as shown in FIG. 10.

Referring to FIGS. 1 and 2 which illustrate the first imaging system (30) detects the topography on the upper surface of the wafer (50) to measure and recognize shifted positions of a plurality of dies for labeling a plurality of laser marks in the next step.

Referring to FIGS. 2 and 7d which illustrate the laser system (10), which refers to information for laser marks to be printed, labels laser marks at the lower surface of the wafer (50) through the unfilled corner of the vacuum module (24) (FIG. 7d).

Referring to FIG. 3 to FIG. 4 that illustrate the six-claw structure of the carrier module (21) on which the wafer (50) is carried is lifted by the surrounding dynamic modules (23) (FIG. 4) and the wafer (50) is not riskily contacted or rubbed by the vacuum module (24); moreover, the pinion component (412) is driven by the dynamic component (413) for a clockwise spin and followed by the gearwheel ring component (411) for a counterclockwise spin so that the vacuum module (24) is actuated finally, as shown from FIG. 7c to FIG. 7d.

Referring to FIG. 4 to FIG. 3 that illustrate the six-claw structure of the carrier module (21) on which the wafer (50) is carried is lowered by the surrounding dynamic modules (23) (FIG. 3) and the vacuum module (24) approaches and contacts the wafer (50); moreover, both the wafer leveling system (20) and the wafer (50) are shifted to position A by the translational mechanism (42) along the negative Y-axis, as shown in FIG. 10.

Accordingly, a laser marking device in the present disclosure, which differs from other laser marking devices and is referred to as creative work in the semiconductor industry, meets patentability and is applied for the patent.

It should be reiterated that the above descriptions presents preferred embodiments, and any equivalent change in specifications, claims, or drawings still belongs to the technical field within the present disclosure with reference to claims hereinafter.

What is claimed is:

1. A laser marking device, comprising a laser system (10), a mobile system (40) over the laser system (10), a wafer leveling system (20) over the mobile system (40), a first imaging system (30) over the wafer leveling system (20) and characterized in that: the wafer leveling system (20) carries and levels a warped wafer (50) to be processed; the mobile system (40) underneath properly adjusts a position of the wafer (50); the first imaging system (30) detects the wafer (50) to recognize a product category shown on the wafer (50) and positioning status; the laser system (10) underneath labels laser marks on the wafer (50).

2. A laser marking device as claimed in claim 1 wherein the wafer leveling system (20) comprises a carrier module (21), a fixture module (22), a dynamic module (23) and a vacuum module (24).

3. A laser marking device as claimed in claim 1 wherein the wafer leveling system (20) is opposite to a second imaging system (31) underneath.

4. A laser marking device as claimed in claim 1 wherein the mobile system (40) comprises a rotary mechanism (41) and a translational mechanism (42).

5. A laser marking device as claimed in claim 4 wherein the rotary mechanism (41) comprises a gearwheel ring component (411), a pinion component (412) and a dynamic component (413).

6. A laser marking device as claimed in claim 5 wherein the gearwheel ring component (411) comprises an upper ring (4111), a lower ring (4112) and a plurality of springs (4113).

7. A method for laser marking comprises steps: (a) a wafer leveling system carries and levels a warped wafer; (b) a first imaging system detects the topography on the upper surface of the wafer to measure positions of a plurality of dies and recognize a plurality of locations for laser marking based on the dies; (c) a laser system refers to information for laser marking on the wafer and marks the wafer at the lower surface through an unfilled corner; (d) the wafer leveling system is spin by a mobile system; (e) the wafer leveling system is horizontally shifted by a mobile system; steps (b) to (e) may be conducted repeatedly.

8. A method for laser marking as claimed in claim 7 wherein the wafer is lifted by a dynamic module in the wafer leveling system after step (c).

9. A method for laser marking as claimed in claim 8 wherein the wafer is lowered by the dynamic module in the wafer leveling system after step (d).

10. A method for laser marking as claimed in claim 7 wherein a second imaging system detects the topography on the back of the wafer and records a plurality of laser marks thereon after step (c).
